(19) United States
(12) Patent Application Publication
(10) Pub. No.: US 2015/0203959 A1
(43) Pub. Date: Jul. 23, 2015

(54) SYSTEMS, DEVICES AND METHODS RELATED TO SOURCE LEVEL COMPENSATION FOR ELECTRON-BEAM EVAPORATORS

(71) Applicant: SKYWORKS SOLUTIONS, INC., Woburn, MA (US)

(72) Inventor: Kezia CHENG, Lowell, MA (US)

(21) Appl. No.: 14/539,959

(22) Filed: Nov. 12, 2014

Related U.S. Application Data
(60) Provisional application No. 61/905,135, filed on Nov. 15, 2013.

(51) Int. Cl. C23C 14/50; C23C 14/54; C23C 14/30

(52) U.S. Cl. CPC C23C 14/50; C23C 14/30; C23C 14/54

(57) ABSTRACT

Source level compensation for electron-beam evaporators. In some embodiments, a source system for an electron-beam evaporator can include a holder implemented to hold a volume of source material to be evaporated into evaporants, and an emitter assembly implemented to generate a beam of electrons. The emitter assembly can include an electron source and be positioned relative to the holder to inhibit contamination of the electron source by at least some of the evaporants. The source system can further include a beam-delivery assembly implemented to provide a trajectory for the beam of electrons from the emitter assembly to a surface of the volume of source material. The source system can further include a compensation system configured to provide an adjustment of an incidence location of the beam of electrons on the surface to compensate for a shift in the incidence location from a desired location on the surface.

### CROSS-REFERENCE TO RELATED APPLICATION(S)

This application claims priority to U.S. Provisional Application No. 61/905,135 filed Nov. 15, 2013, entitled SYSTEMS, DEVICES AND METHODS RELATED TO SOURCE LEVEL COMPENSATION FOR AN ELECTRON-BEAM EVAPORATOR, the disclosure of which is hereby expressly incorporated by reference herein in its entirety.

### BACKGROUND

1. Field

The present disclosure generally relates to source level compensation for electron-beam evaporators.

2. Description of the Related Art

Electron-beam (e-beam) evaporation is a deposition process where source material is heated by a beam of electrons to yield evaporated atoms that are deposited on exposed surfaces. E-beam evaporation can be preferable over thermal evaporation when higher density depositions are desired, which can be achieved by a relatively large amount of energy delivered to the source material by electrons.

### SUMMARY

According to some implementations, the present disclosure relates to a source system for an electron-beam evaporator. The system includes a holder implemented to hold a volume of source material to be evaporated into evaporants, and an emitter assembly implemented to generate a beam of electrons. The emitter assembly includes an electron source and is positioned relative to the holder to inhibit contamination of the electron source by at least some of the evaporants. The system further includes a beam-delivery assembly implemented to provide a trajectory for the beam of electrons from the emitter assembly to a surface of the volume of source material. The system further includes a compensation system configured to provide an adjustment of an incidence location of the beam of electrons on the surface to compensate for a shift in the incidence location from a desired location on the surface.

In some embodiments, the holder can define a cup-shaped recess dimensioned to hold the volume of source material. The cup-shaped recess can have an opening that generally faces a direction to which travel of evaporants is desired. The holder can include a hearth or a crucible.

In some embodiments, the opening of the cup-shaped recess can generally face an upward direction. The emitter assembly can be positioned below the holder such that the evaporants travelling through the upward facing opening of the cup-shaped recess are inhibited from reaching the electron source. The beam-delivery assembly can include a magnetic field source configured to provide a magnetic field. The magnetic field can be configured to provide a curved trajectory for at least a portion of the trajectory of the beam of electrons. The magnetic field can be a substantially static magnetic field. The static magnetic field can include a magnitude and a direction selected to bend the beam of electrons by approximately 270 degrees.

In some embodiments, the compensation system can include a movement component configured to provide a movement that changes relative position between the holder and the emitter assembly. The movement can be selected to compensate for a shift in the incidence location from a center location resulting from lowering of the surface as the volume of source material decreases. In some embodiments, the movement can include a rotational movement of either or both of the holder and the emitter assembly.

In some embodiments, the movement can include a translational movement of either or both of the holder and the emitter assembly. The translational movement can include a movement of the emitter assembly, where the holder can remain substantially stationary. The translational movement of the emitter assembly can include a direction component parallel to a horizontal direction. The horizontal-direction movement of the emitter assembly can be selected to be generally opposite from a curvature direction of the beam of electrons at the incidence location.

In some embodiments, the compensation system can include a beam adjustment component configured to provide a change in the trajectory of the beam of electrons. The change can be selected to compensate for a shift in the incidence location from a center location resulting from lowering of the surface as the volume of source material decreases.

In some embodiments, the beam adjustment component can include a time-dependent magnetic field source. The beam adjustment component can include a plurality of magnetic field sources, with at least one magnetic field source having time-dependence capability. The beam adjustment component can include an electric field source configured to provide an electric field to facilitate the adjustment of incidence location of the beam of electrons.

In some embodiments, the compensation system can include a controller configured to control or facilitate the adjustment of incidence location of the beam of electrons. At least a portion of the adjustment of incidence location of the beam of electrons can be performed automatically by the compensation system. The adjustment of the incidence location of the beam of electrons can be based at least in part on one or more operating parameters. The one or more operating parameters can include one or more of material type, deposition rate, elapsed time, and desired deposition thickness.

In a number of implementations, the present disclosure relates to a method for delivering a beam of electrons in an electron-beam evaporator. The method includes positioning a volume of source material to be evaporated into evaporants, and generating a beam of electrons from an electron source. The generating of the beam of electrons is performed to inhibit contamination of the electron source by at least some of the evaporants. The method further includes providing a trajectory for the beam of electrons to deliver the beam of electrons to an incidence location on a surface of the volume of source material. The method further includes adjusting the incidence location upon indication that the incidence location has shifted from a desired location on the surface.

According to some teachings, the present disclosure relates to an electron-beam evaporator that includes a chamber having an interior volume. The chamber is implemented to be capable of providing a desired level of vacuum for the interior volume. The electron-beam evaporator further includes a substrate holder implemented within the interior volume. The substrate holder is configured to hold one or more substrates, with each having a surface configured to receive evaporants. The electron-beam evaporator further includes a source system implemented within the interior volume. The source system includes a holder implemented to hold a volume of source material to be evaporated into the evaporants. The source system further includes an emitter assembly implemented to generate a beam of electrons. The emitter assembly includes an electron source, and is positioned relative to the holder to inhibit contamination of the electron source by at least some of the evaporants. The source system further includes a beam-delivery assembly implemented to provide a trajectory for the beam of electrons from the emitter assembly to a surface of the volume of source material. The source system further includes a compensation system configured to provide an adjustment of an incidence location of the beam of electrons on the surface to compensate for a shift in the incidence location from a desired location on the surface.

In some implementations, the present disclosure relates to a method for operating an electron-beam evaporator. The method includes positioning one or more substrates within a chamber, with each substrate having a surface configured to receive evaporants. The method further includes positioning a volume of source material in the chamber, and forming a desired level of vacuum in the chamber. The method further includes delivering a beam of electrons from a source system to an incidence location on a surface of the volume of source material to yield the evaporants. The method further includes adjusting the incidence location based on one or more operating parameters or upon indication that the incidence location has shifted from a desired location on the surface.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 schematically depicts an electron-beam (e-beam) evaporator having one or more features as described herein.

FIG. 2 shows an example e-beam configuration where different levels of a source material volume result in displacement of beam incidence location from a desired center location.

FIG. 3 shows an example plot of the displacement of FIG. 2 as a function of operating time.

FIG. 4 shows that in some embodiments, an e-beam evaporator can be configured so that displacement of beam incidence location can be reduced or eliminated.

FIG. 5 schematically shows that the e-beam evaporator of FIG. 4 can include one or more compensation components configured to compensate for the displacement effect of FIGS. 2 and 3.

FIG. 6 shows that in some embodiments, the compensation of FIG. 5 can be achieved by controlled movement of either or both of an electron emitter and a source material holder.

FIG. 7 shows an example where the electron emitter is moved along a first direction in a controlled manner to facilitate the compensation of FIG. 6.

FIG. 8 shows an example where the electron emitter is moved along a second direction in a controlled manner to facilitate the compensation of FIG. 6.

FIG. 9 shows an example where the source material holder is moved along a first direction in a controlled manner to facilitate the compensation of FIG. 6.

FIG. 10 shows an example where the source material holder is moved along a second direction in a controlled manner to facilitate the compensation of FIG. 6.

FIG. 11 shows that in some embodiments, the compensation of FIG. 5 can be achieved by providing time-varying electron-steering magnetic field strength as the level of source material volume changes.

FIG. 12 shows that in some embodiments, the compensation of FIG. 5 can be achieved by providing spatial-varying electron-steering magnetic field strength as the level of source material volume changes.

FIG. 13 shows that in some embodiments, the compensation of FIG. 5 can be achieved by providing varying electric field strength as the level of source material volume changes.

FIG. 14 shows a process that can be implemented to compensate for displacement of electron beam incidence location resulting from a decrease in volume of source material.

FIG. 15 shows a process that can be implemented to perform the compensation of FIG. 14 upon indication of a change in the electron beam incidence location.

FIG. 16 shows a process that can be a more specific example of the process of FIG. 15, where the change can be deduced from duration of operation.

FIG. 17 shows another process that can be a more specific example of the process of FIG. 15, where the change can be deduced from monitoring the electron beam incidence location.

FIG. 18 shows an example e-beam evaporator device that can benefit from one or more features of the present disclosure.

### DETAILED DESCRIPTION OF SOME EMBODIMENTS

The headings provided herein, if any, are for convenience only and do not necessarily affect the scope or meaning of the claimed invention.

Electron-beam (e-beam) evaporation is a deposition process where source material is heated by a beam of electrons to yield evaporated atoms that are deposited on exposed surfaces. E-beam evaporation can be preferable over thermal evaporation when higher density depositions are desired, which can be achieved by a relatively large amount of energy delivered to the source material by electrons. Further, under ideal operating conditions, electron-beam only heats the source material and not a holder such as a crucible. Since the crucible is not heated as in thermal evaporation, contamination from the crucible is typically lowered.

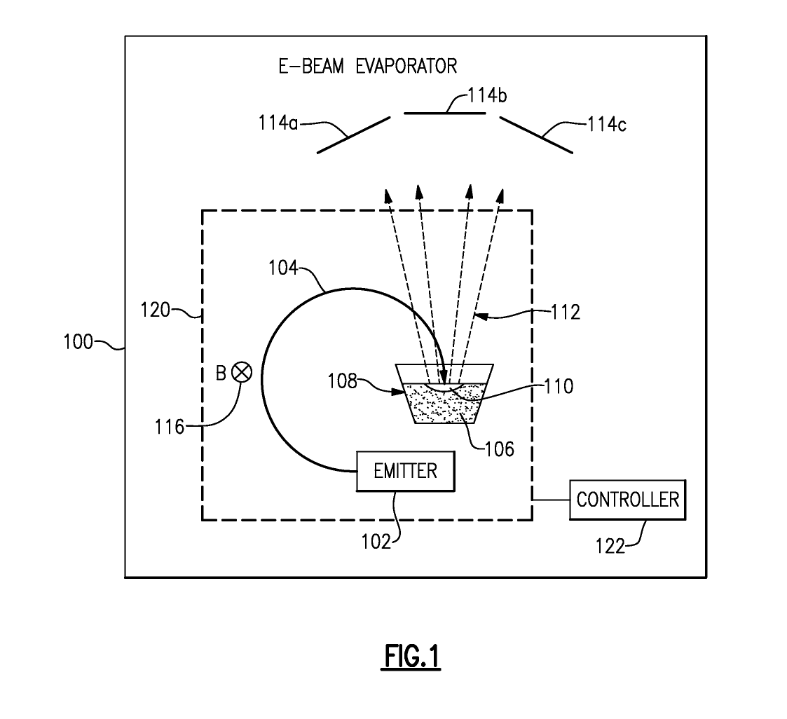

FIG. 1 schematically depicts an e-beam evaporator 100 having a volume of source material 106 held in a holder such as a crucible 108 (also referred to herein as a hearth). A beam of electrons 104 is shown to be directed to a surface (e.g., upper surface) of the source material so as to yield source particles 112 evaporating from a heated region 110. Such source particles 112 (also referred to herein as evaporants) can be directed to any available directions from the heated region 110; and can travel in a line-of-sight manner. Thus, in the example of FIG. 1, parts (e.g., semiconductor wafers) 114a-114c on which a film of the source material is to be formed can be positioned appropriately to receive such source particles 112.

Because of the foregoing nature of the evaporants, an emitter 102 of electron-beam is typically positioned so that evaporants generally do not reach and undesirably coat the emitter 102. For example, the emitter 102 is shown to be positioned below the source material holder 108 so as to be out of the line-of-sight of the evaporants 112.

To deliver the electron-beam from the emitter 102 to the upper surface of the source material 106, magnetic field (B) can be provided to bend the trajectories of the electrons. In the example of FIG. 1, a constant static magnetic field is depicted as going into the plane of illustration. Accordingly, an electron travelling within the plane with a speed of v experiences a magnetic force with a magnitude of evB and a direction that is perpendicular to the direction of travel. The resulting motion of the electron generally defines, for example, about 270 degrees of a circular path, thereby allowing electrons from the “hidden” emitter 102 to be delivered to the upper surface of the source materials 106 in a curved manner.

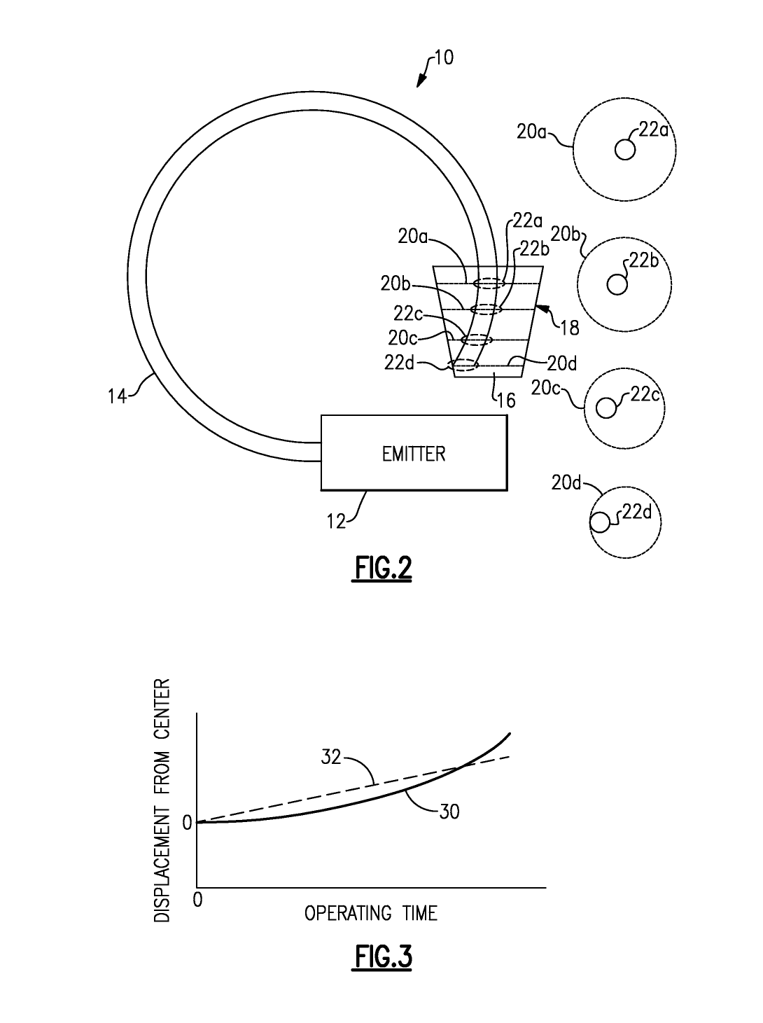

As described herein in reference to FIGS. 2 and 3, such a curved nature of the electron-beam 104 can result in some undesirable effects when the electrons are incident on the upper surface of the source material 106. FIG. 1 further shows that in some embodiments, an e-beam evaporator 100 can include a compensation component 120 that can be configured to mitigate such undesirable effects. Non-limiting examples of the compensation component 120 are described herein in greater detail.

FIG. 1 further shows that in some embodiments, control of some or all of functionalities associated with the compensation component 120 can be provided or facilitated by a controller 122. Such a controller can be located at, near, or remotely and be in communication with at least some portion of the compensation component 120 so as to effectuate one or more control functionalities.

For the purpose of description, it will be understood that an e-beam evaporator can include an electron-emitter and a source material holder; and may or may not include hardware for holding substrates such as wafers. It will also be understood that a beam of electrons (also referred to herein as electron-beam or e-beam) can include one or more electrons travelling in a similar trajectory; and such electrons can be sharply or loosely collimated to achieve heating of the source material.

FIG. 2 shows an example operating configuration 10 where a curved trajectory 14 of electrons from an emitter 12 is incident on an upper surface of a volume of source material 16 being held in a holder 18 such as a crucible. Suppose that initially, the volume of source material has an upper surface 20a. As incident electrons heat and form a heated region 22a and cause evaporation, the volume of source material can decrease over time. For example, as evaporation continues, the volume of source material can decrease to yield progressively lower surfaces 20b, 20c and 20d, with corresponding heated regions 22b, 22c and 22d.

One can see that because of the curved trajectory 14 of the electrons, lateral position of the heated region on the corresponding surface shifts inward as the surface is lowered in the foregoing manner. On the right side of FIG. 2, plan views of the example surfaces 20a-20d and their corresponding heated regions 22a-22d are shown.

Such a shift in lateral position of the heated region 22 can create a number of problems. For example, such a shift can change the tooling factor (and therefore final thickness) of the material being evaporated because the vapor cloud may be affected by beam-incidence position. In another example, and as depicted by the example lateral position of the heated region 22d, when the lateral position of the beam-incidence location shifts sufficiently, some or all of the electron beam and/or the heated region can interact with the holder 18. Such an interaction with the holder 18 can cause problems such as metal spitting release of contaminants into the evaporants.

FIG. 3 shows an example of an increase in lateral displacement of the heated region (22 in FIG. 2) as a function of operating time when the source material being evaporated is not replaced. In some situations, such a relationship can be approximately linear (e.g., 32) or non-linear (e.g., 30). In the example shown in FIG. 2, the holder 18 has an angled side wall, so that the opening at the top has a larger lateral area than the lateral area of the floor at the bottom. For such a holder geometry, as well as many bowl or concave shaped holders, one can see that as the surface of the volume of source material is lowered towards the floor, the margin between the lateral center and the edge of the surface decreases. Thus, it can be desirable to be able to maintain the beam incidence location at or near the center, especially when the surface level is lowered.

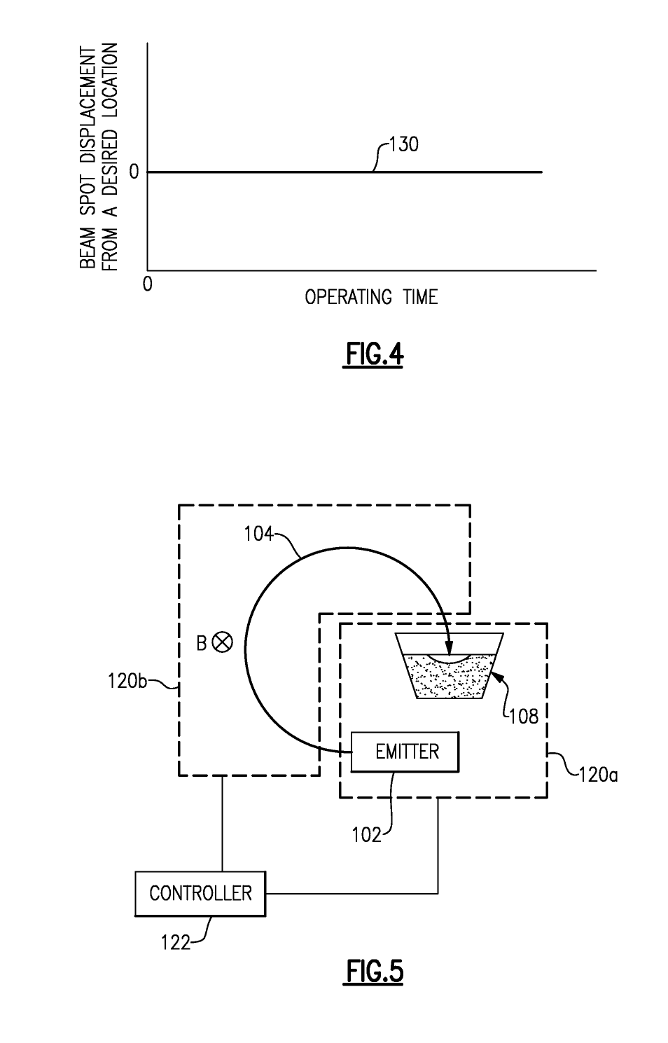

FIG. 4 shows an example of a desirable operating configuration that can be implemented by utilizing one or more features of the present disclosure. In some embodiments, a beam incidence location can be provided at a desired lateral location (e.g., at or near center) initially, and such a lateral location can be substantially maintained over some operating time (e.g., as depicted by a substantially flat line 130), even when the source material being evaporated is not replaced. Various examples of how such uniformity can be achieved are described herein in greater detail.

In various examples described herein, beam incidence location being at or close to the center is generally assumed. However, it will be understood that one or more features of the present disclosure can be implemented to control incidence location and/or incidence angle of the electron-beam. Thus, the center location can be an example of a desired beam incidence location. In some situations, it may be desirable to be able to place the electron-beam at another lateral location; and such a configuration can be achieved by utilizing one or more features as described herein.

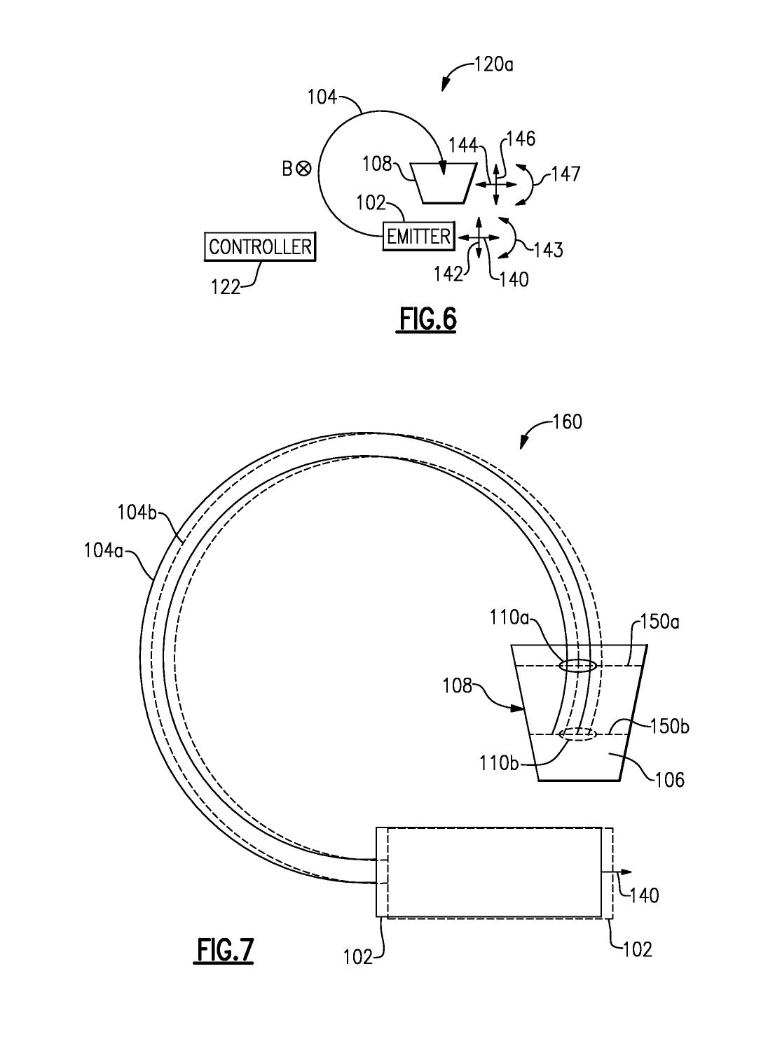

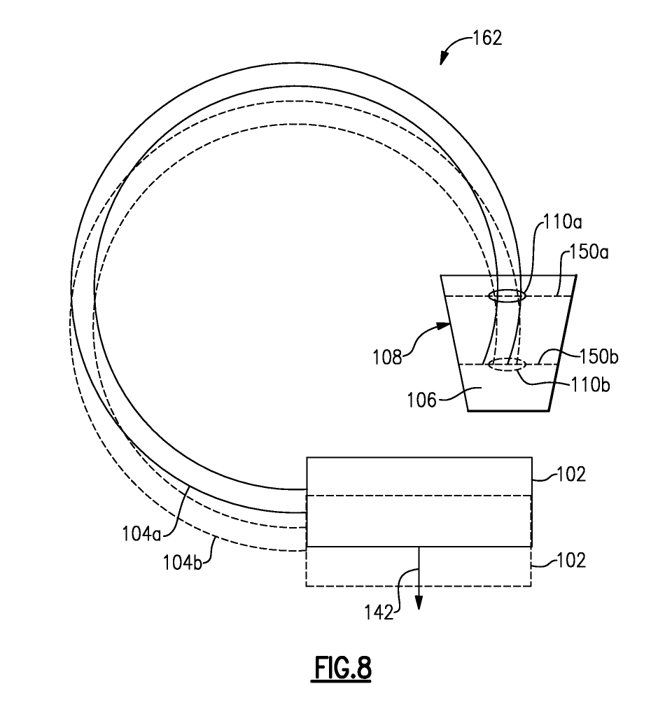

FIG. 5 shows that in some embodiments, one or more features associated with compensation techniques as described herein to achieve the foregoing control of beam incidence location and/or incidence angle can be implemented by, for example, adjusting the relative geometry of an electron emitter 102 and a volume of source material being held in a holder 108. Such an implementation is depicted in FIG. 5 as 120a. Various non-limiting examples of such an implementation are described herein in greater detail in reference to FIGS. 6-10.

In some embodiments, such compensation techniques can also be implemented by, for example, adjusting the geometry of the electron beam 104 itself. Such an implementation is depicted in FIG. 5 as 120b. Various non-limiting examples of such an implementation are described herein in greater detail in reference to FIGS. 11-13. In some embodiments one or more features associated with the example implementations 120a, 120b can be combined.

FIG. 5 further shows that in some embodiments, control of one or more functionalities associated with either or both of the compensation implementations 120a, 120b can be provided and/or facilitated by a controller 122. Additional details concerning such a controller are described herein.

FIG. 6 shows that in some embodiments, a compensation configuration 120a can be implemented by a relative motion between an emitter 102 and a holder 108 holding a volume of source material. Such a relative motion can include a motion of the emitter 102 while the holder 108 remains substantially stationary, a motion of the holder 108 while the emitter 102 remains substantially stationary, motion of each of the emitter 102 and the holder 108, or any combination thereof. For the motion of the emitter 102, the emitter 102 can be moved in directions having components in, for example, horizontal (e.g., arrow 140) and/or vertical (e.g., arrow 142) directions. The emitter 102 can also be rotated as depicted (e.g., arrow 143). For the motion of the holder 108, the holder 108 can be moved in directions having components in, for example, horizontal (e.g., arrow 144) and/or vertical (e.g., arrow 146) directions. The holder 108 can also be rotated as depicted (e.g., arrow 147).

Although the foregoing example motions are described in the context of the example plane defined by the curved trajectory 104 of electrons, it will be understood that either or both of the emitter 102 and the holder 108 can also move out of such a plane. It will also be understood that some or all of the foregoing movements can be controlled or facilitated by a controller 122.

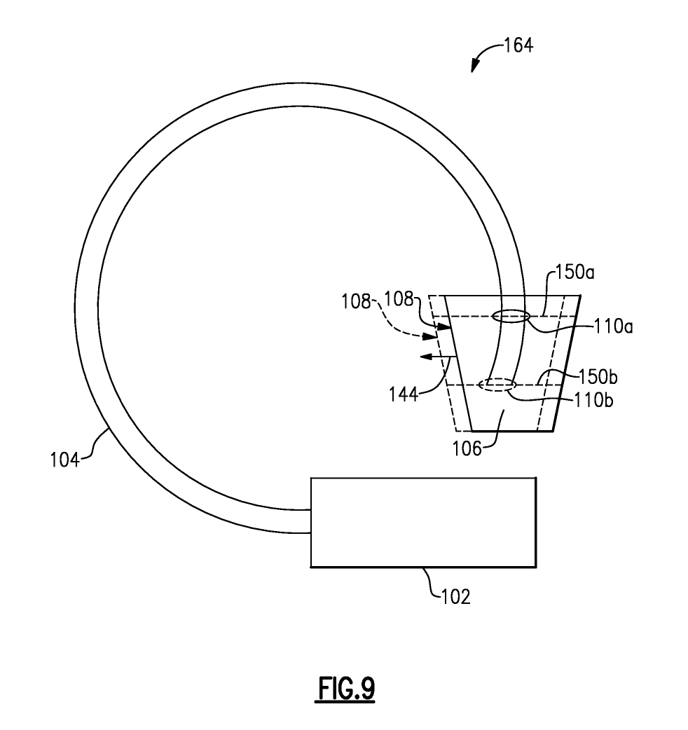

FIG. 7 shows an example of FIG. 6, where a compensation movement configuration 160 can include a shift (e.g., horizontal) of the emitter 102. Before such a horizontal shift (depicted as an arrow 140) of the emitter 102, a trajectory of the electron-beam 104a (in solid lines) is shown to be incident on a surface 150a of a volume of source material 106 within the holder 108 when the surface 150a is relatively high (e.g., at the beginning of an evaporation operation). The electron-beam 104a is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 7, such a lowered surface is depicted as a surface 150b. To accommodate such a lowered surface, the emitter 102 can be shifted horizontally as shown so as to yield an electron-beam 104b (in dashed lines) trajectory that is also shifted (relative to the beam 104a). Such a shift is shown to compensate for the shifting of the heated region on the lowered surface 150b, by shifting the incidence location of the beam 104b back to a generally central location to yield a heated region 110b thereon.

FIG. 8 shows an example of FIG. 6, where a compensation movement configuration 162 can include a shift (e.g., vertical) of the emitter 102. Before such a vertical shift (depicted as an arrow 142) of the emitter 102, a trajectory of the electron-beam 104a (in solid lines) is shown to be incident on a surface 150a of a volume of source material 106 within the holder 108 when the surface 150a is relatively high (e.g., at the beginning of an evaporation operation). The electron-beam 104a is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 8, such a lowered surface is depicted as a surface 150b. To accommodate such a lowered surface, the emitter 102 can be shifted vertically as shown so as to yield an electron-beam 104b (in dashed lines) trajectory that is also shifted (relative to the beam 104a). Such a shift is shown to compensate for the shifting of the heated region on the lowered surface 150b, by shifting the incidence location of the beam 104b back to a generally central location to yield a heated region 110b thereon.

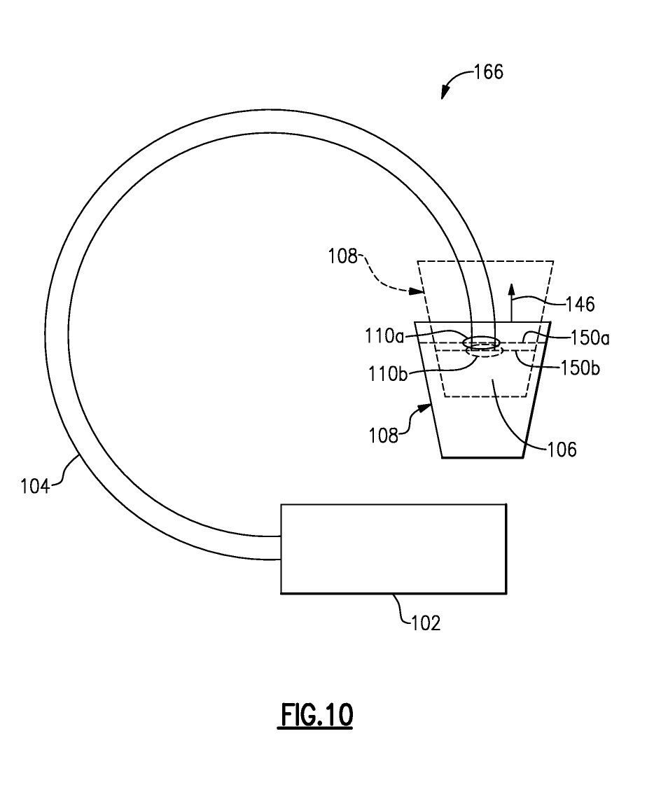

FIG. 9 shows an example of FIG. 6, where a compensation movement configuration 164 can include a shift (e.g., horizontal) of the holder 108. Before such a horizontal shift (depicted as an arrow 144) of the holder 108, a trajectory of the electron-beam 104 is shown to be incident on a surface 150a of a volume of source material 106 within the holder 108 when the surface 150a is relatively high (e.g., at the beginning of an evaporation operation). The electron-beam 104 is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 9, such a lowered surface is depicted as a surface 150b. To accommodate such a lowered surface, the holder 108 can be shifted horizontally as shown such that its position is shifted relative to the electron-beam 104. Such a shift is shown to compensate for the shifting of the heated region on the lowered surface 150b, by shifting the incidence location of the beam 104 back to a generally central location to yield a heated region 110b thereon.

FIG. 10 shows an example of FIG. 6, where a compensation movement configuration 166 can include a shift (e.g., vertical) of the holder 108. Before such a vertical shift (depicted as an arrow 146) of the holder 108, a trajectory of the electron-beam 104 is shown to be incident on a surface 150a of a volume of source material 106 within the holder 108 when the surface 150a is relatively high (e.g., at the beginning of an evaporation operation). The electron-beam 104 is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 10, such a lowered surface is depicted as a surface 150b. To accommodate such a lowered surface, the holder 108 can be shifted vertically as shown such that its position is shifted relative to the electron-beam 104. Such a shift is shown to compensate for the shifting of the heated region on the lowered surface 150b, by shifting the incidence location of the beam 104 back to a generally central location to yield a heated region 110b thereon.

Based on the foregoing examples described in reference to FIGS. 6-10, one can see that either or both of the emitter 102 and the holder 108 can be moved (e.g., displaced) relative to each other so as to obtain a desired incident location of the electron-beam (e.g., at or close to a center) at different levels of the surface of the volume of source material 106. In some embodiments, such movements can be implemented by, for example, mounting either or both of the emitter 102 and the holder 108 on their/its respective movement mechanism(s) that can be actuated by control signal(s) to yield desired displacement(s) with sufficient spatial resolution. Examples of such control signals are described herein in greater detail.

Based on the foregoing examples described in reference to FIGS. 6-10, one can also see that either or both of the emitter 102 and the holder 108 can be rotated so as to obtain, for example, a desired incidence angle of the electron-beam at different levels of the surface of the volume of source material 106. By way of an example, FIGS. 7 and 10 depict compensation configurations where the emitter 102 and the holder 108 are shifted horizontally, respectively. In each case, such a horizontal shift can restore the beam incidence location at or close to the center. However, the beam 104b is shown to have an incident angle (relative to a normal of the surface 150b) greater than that of the beam 104a.

There may be situations where having a selected incident angle of the electron-beam (e.g., at or close to normal) is desired. In such situations, either or both of the emitter 102 and the holder 108 can be rotated (e.g., as depicted by arrows 143, 147 in FIG. 6) to obtain desired incident angles at different levels of the surface of the volume of source material 106. In some embodiments, it may be preferable to rotate the emitter 102 so as to maintain a selected evaporation pattern associated with a selected orientation of the holder 108.

In some embodiments, and as described in reference to FIG. 5, compensation of shifts in beam incidence location and/or orientation can also be implemented by adjusting the geometry of the electron beam 104 itself. Such an implementation is depicted in FIG. 5 as 120b.

FIG. 11 shows an example of the implementation 120b of FIG. 5, where a compensation configuration 170 can include an adjustment of an electron-beam being delivered to a volume of source material 106 within the holder 108. Before such an adjustment, an electron-beam 172 (in solid lines) is shown to have a trajectory so as to be incident on a surface 150a of the volume of source material 106 within the holder 108 when the surface 150a is relatively high (e.g., at the beginning of an evaporation operation). The electron-beam 172 is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 11, such a lowered surface is depicted as a surface 150b. To accommodate such a lowered surface, the foregoing electron-beam 172 can be adjusted to yield an adjusted electron-beam trajectory 174 (in dashed lines). Such an adjustment is shown to compensate for the shifting of the heated region on the lowered surface 150b, by shifting the beam incidence location back to a generally central location to yield a heated region 110b thereon.

In the example of FIG. 11, the beam trajectory adjustment can be implemented by providing a plurality of different magnetic field B(t) strengths during an evaporation operation. For example, at time t=tₐ (e.g., at the beginning of an evaporation operation), B(tₐ) can have a field strength value that yields the example trajectory 172. At time t=t_{b} corresponding to the lowered surface 150b, B(t_{b}) can have a field strength value that yields the example trajectory 174. In some embodiments, magnitude of B(t_{b}) can be less than the magnitude of B(tₐ).

FIG. 12 shows an example of the implementation 120b of FIG. 5, where a compensation configuration 180 can include an adjustment of an electron-beam being delivered to a volume of source material 106 within the holder 108. Before such an adjustment, an electron-beam 182 is shown to be delivered to a surface 150a of the volume of source material 106 within the holder 108 in a configuration 184 (in solid lines), when the surface 150a is relatively high (e.g., at the beginning of an evaporation operation). The delivered electron-beam 184 is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 12, such a lowered surface is depicted as a surface 150b. To accommodate such a lowered surface, the foregoing delivered electron-beam configuration 184 can be adjusted to yield an adjusted electron-beam configuration 186 (in dashed lines). Such an adjustment is shown to compensate for the shifting of the heated region on the lowered surface 150b, by shifting the beam incidence location back to a generally central location to yield a heated region 110b thereon.

In the example of FIG. 12, the beam delivery adjustment can be implemented by providing different magnetic field strengths at different locations, with at least one of such magnetic field strengths being adjustable during an evaporation operation. For example, two magnetic field regions B1 and B2 can be provided as shown. In the example, B1 can be a static field, and B2 can be an adjustable field. At time t=tₐ (e.g., at the beginning of an evaporation operation), B2(tₐ) can have a field strength value that yields the example delivered beam configuration 184. At time t=t_{b} corresponding to the lowered surface 150b, B2(t_{b}) can have a field strength value that yields the example delivered beam configuration 186. In some embodiments, magnitude of B2(t_{b}) can be less than the magnitude of B1(tₐ).

FIG. 13 shows an example of the implementation 120b of FIG. 5, where a compensation configuration 190 can include an adjustment of an electron-beam being delivered to a volume of source material 106 within the holder 108. Before such an adjustment, an electron-beam 192 is shown to be delivered to a surface 150a of the volume of source material 106 within the holder 108 in a configuration 194 (in solid lines), when the surface 150a is relatively high (e.g., at the beginning of an evaporation operation). The delivered electron-beam 194 is depicted to be incident at a generally center region of the surface 150a so as to yield a heated region 110a.

As described herein in reference to FIG. 2, such a heated region can shift laterally on the surface of the volume as the volume decreases and the surface is lowered. In the example of FIG. 13, such a lowered surface is depicted as a surface 150b. To accommodate such a lowered surface, the foregoing delivered electron-beam configuration 194 can be adjusted to yield an adjusted electron-beam configuration 196 (in dashed lines). Such an adjustment is shown to compensate for the shifting of the heated region on the lowered surface 150b, by shifting the beam incidence location back to a generally central location to yield a heated region 110b thereon.

In the example of FIG. 13, the beam delivery adjustment can be implemented by providing an electric field (E) that can be applied in a selected manner during an evaporation operation. For example, a magnetic field B can be a static field, and at time t=tₐ (e.g., at the beginning of an evaporation operation), the electric field E can be turned off so that the delivered beam configuration 194 is due to the static magnetic field B. At time t=t_{b} corresponding to the lowered surface 150b, the electric field E can be turned on so as to alter the trajectory of the delivered beam (194) and yield the adjusted beam (196).

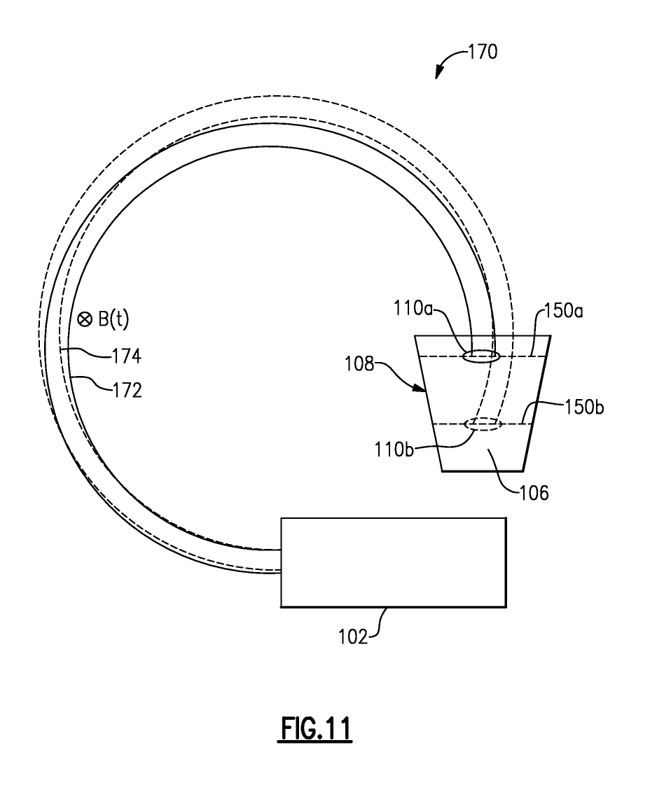

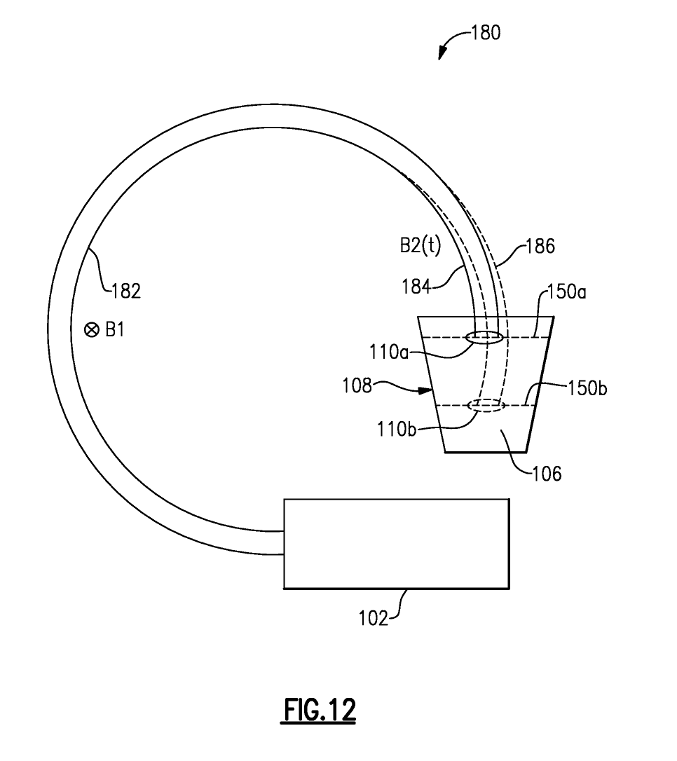

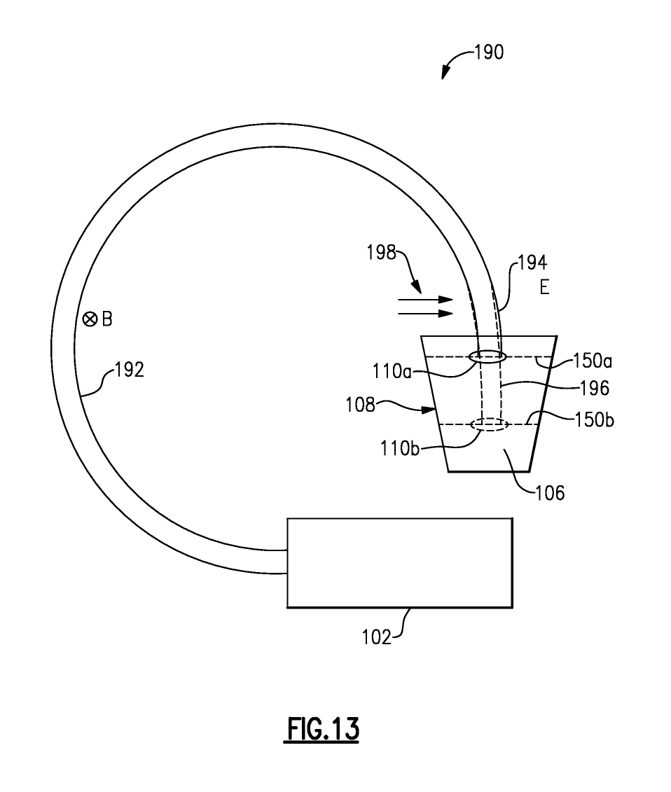

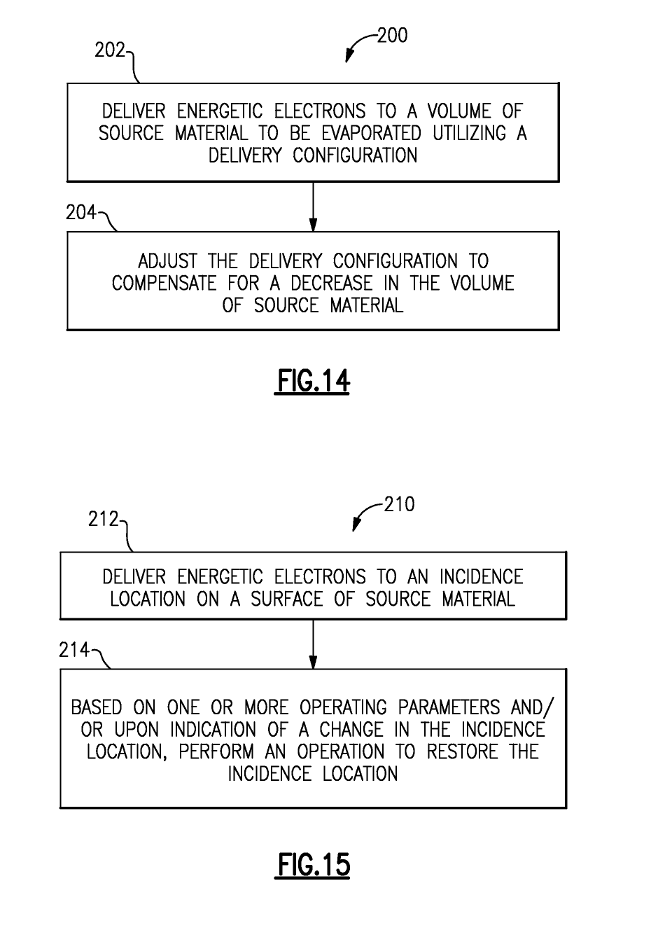

FIG. 14 shows a process 200 that can be implemented to perform and/or facilitate compensation techniques having one or more features as described herein. In block 202, energetic electrons can be delivered to a volume of source material to be evaporated utilizing a delivery configuration. In block 204, the delivery configuration can be adjusted to compensate for a decrease in the volume of source material.

FIG. 15 shows a process 210 that can be implemented as a more specific example of the process 200 of FIG. 14. In the process 210 of FIG. 15, the decrease in the volume of source material can be detected by a change in an incidence location of the energetic electrons. In block 212, such energetic electrons can be delivered to an incidence location on a surface of the volume of source material. In block 214, an operation to restore the incidence location can be performed based on one or more operating parameters and/or upon indication of a change in the incidence location. For example, operating parameters such as source material type, deposition rate, elapsed time of operation, and the total desired deposition thickness can be utilized to generate an adjustment profile during the evaporation operation. In some implementations, some or all of such generation of the adjustment profile can be performed automatically by a processor based on an algorithm and related data stored in a storage medium such as a non-transient computer-readable medium. In some implementations, some or all of such an adjustment profile can be effectuated automatically under the control of a processor during the evaporation operation to restore the incidence location.

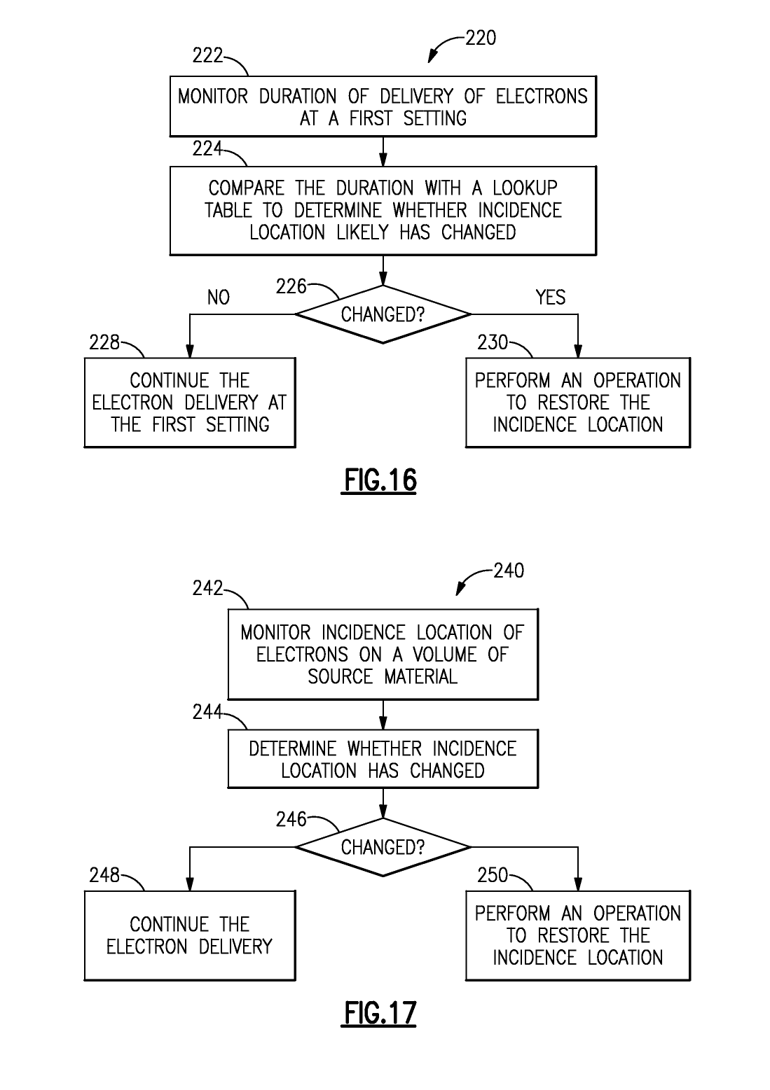

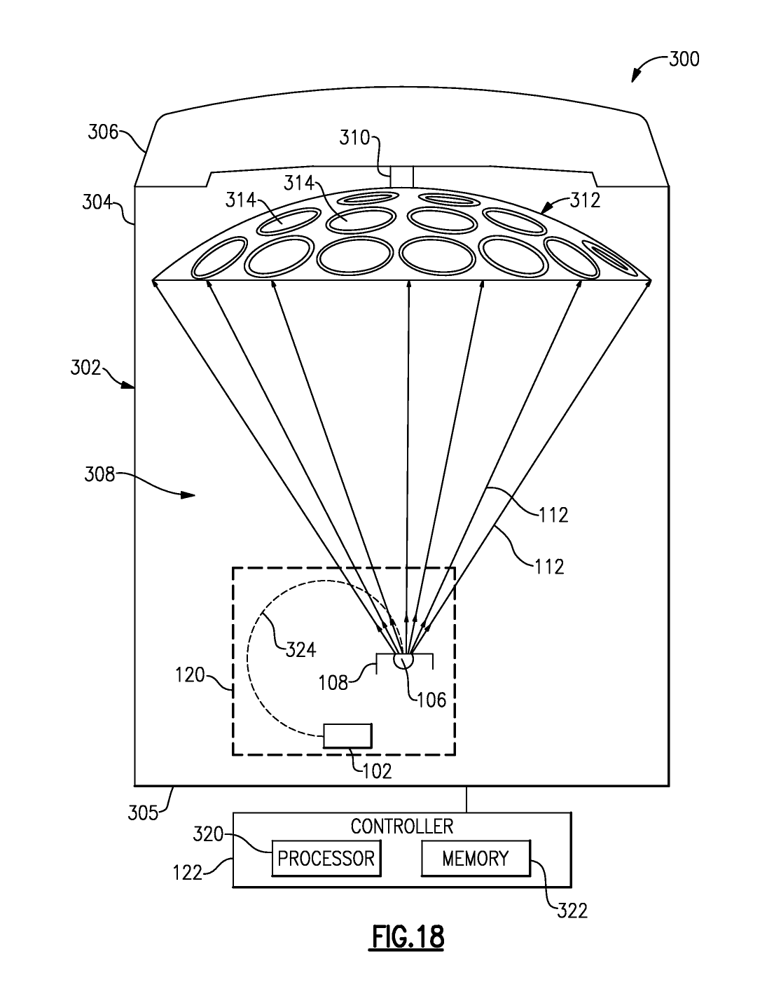

FIGS. 16 and 17 show examples of how a change in incidence location can be estimated so as to, for example, trigger an operation to restore the incidence location that has shifted. In FIG. 16, a process 220 can be implemented where such an estimation of incidence location can be based on a lookup table having, for example, a plurality of data corresponding to surface levels after different operating times. Such data can be based on previous measurements, as well as interpolation and/or extrapolation.

In block 222, duration of delivery of electrons at a first setting can be monitored. In block 224, the monitored duration can be compared with a lookup table to allow determination of whether there has been a change in incidence location. Such a lookup table can be similar to the foregoing example. In a decision block 226, the process 220 can proceed based on the determination of such a change. If “No,” the process 220 can continue the delivery of electron-beam at the first setting in block 228. If “Yes,” the process 220 can perform an operation to restore the incidence location in block 230.

In FIG. 17, a process 240 can be implemented where an estimation of incidence location can be based on a measurements. Such measurements can be based on, for example, an optical sensor such as a camera. A heated region associated with an incidence location can be determined relative to the surface of the source material; and such information can be used to estimate a change in the incidence location. In some implementations, such estimation in incidence location change can be effectuated automatically by a processor utilizing the sensed data and any existing data such as calibration and geometry data. Based on such estimation, a control signal can be generated to yield an operation to restore the incidence location.

In block 242, incidence location of electrons on a volume of source material can be monitored. In block 244, the process 240 can determine whether there has been a change in incidence location. In a decision block 246, the process 240 can proceed based on the determination of such a change. If “No,” the process 240 can continue the delivery of electrons at the current setting in block 248. If “Yes,” the process 240 can perform an operation to restore the incidence location in block 250.

FIG. 18 shows an example evaporator device 300 that can be configured to include a compensation component 120 having one or more features as described herein. The compensation component 120 is depicted as being implemented to provide adjustments in delivery of an electron-beam 324 from an emitter 102 to a volume of source material 106 being held by a holder 108. Various examples of how adjustments can be made are described herein in reference to, for example, FIGS. 5-17.

Incidence of electrons on the source material 106 results in heated region, from which evaporants 112 are emitted. Such evaporants are depicted as travelling in their respective lines of sight to thereby be deposited on exposed surfaces of substrates such as semiconductor wafers 314. The example wafers 314 can be held in desired locations and orientations in a wafer-holder 312 to receive the evaporants 112. In the example shown, the wafer-holder 312 can be configured to rotate by a rotating mechanism 310 that couples the wafer-holder 312 to a dome assembly 306. Such a rotation of the wafer-holder 312 can yield a more uniform deposition of evaporants among the various wafers 314.

In the example shown in FIG. 18, the dome assembly 306, a side wall 304, and a floor 305 can form a chamber 302 that includes an internal volume 308. Such a volume can be provided with an appropriate level of vacuum to facilitate the evaporation process.

As described herein, some or all of the compensation techniques for delivering a beam of electrons to a desired location can be controlled and/or facilitated by a controller 122. Such a controller can include a processor 320 and a memory 322 for storing, for example, lookup tables and executable instructions. Such a memory can be a computer readable medium (CRM), including a non-transitory CRM.

In some embodiments, some or all portions of the controller 122 can be located with the evaporator 300, remotely located from the evaporator 300, or any combination thereof. It will be understood that components of the controller itself may be located generally together, in communication from remote locations, or any combination thereof.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A source system for an electron-beam evaporator, the system comprising:
a holder implemented to hold a volume of source material to be evaporated into evaporants;
an emitter assembly implemented to generate a beam of electrons, the emitter assembly including an electron source and positioned relative to the holder to inhibit contamination of the electron source by at least some of the evaporants;
a beam-delivery assembly implemented to provide a trajectory for the beam of electrons from the emitter assembly to a surface of the volume of source material; and
a compensation system configured to provide an adjustment of an incidence location of the beam of electrons on the surface to compensate for a shift in the incidence location from a desired location on the surface.

2. The source system of claim 1 wherein the holder defines a cup-shaped recess dimensioned to hold the volume of source material, the cup-shaped recess having an opening that generally faces a direction to which travel of evaporants is desired.

3. The source system of claim 2 wherein the emitter assembly is positioned below the holder such that the evaporants travelling through the upward facing opening of the cup-shaped recess are inhibited from reaching the electron source.

4. The source system of claim 1 wherein the compensation system includes a movement component configured to provide a movement that changes relative position between the holder and the emitter assembly, the movement selected to compensate for a shift in the incidence location from a center location resulting from lowering of the surface as the volume of source material decreases.

5. The source system of claim 4 wherein the movement includes a rotational movement of either or both of the holder and the emitter assembly.

6. The source system of claim 4 wherein the movement includes a translational movement of either or both of the holder and the emitter assembly.

7. The source system of claim 6 wherein the translational movement includes a movement of the emitter assembly.

8. The source system of claim 7 wherein the holder remains substantially stationary.

9. The source system of claim 7 wherein the translational movement of the emitter assembly includes a direction component parallel to a horizontal direction.

10. The source system of claim 9 wherein the horizontal-direction movement of the emitter assembly is selected to be generally opposite from a curvature direction of the beam of electrons at the incidence location.

11. The source system of claim 1 wherein the compensation system includes a beam adjustment component configured to provide a change in the trajectory of the beam of electrons, the change selected to compensate for a shift in the incidence location from a center location resulting from lowering of the surface as the volume of source material decreases.

12. The source system of claim 11 wherein the beam adjustment component includes a time-dependent magnetic field source.

13. The source system of claim 11 wherein the beam adjustment component includes a plurality of magnetic field sources, at least one magnetic field source having time-dependence capability.

14. The source system of claim 11 wherein the beam adjustment component includes an electric field source configured to provide an electric field to facilitate the adjustment of incidence location of the beam of electrons.

15. The source system of claim 1 wherein the compensation system includes a controller configured to control or facilitate the adjustment of incidence location of the beam of electrons.

16. The source system of claim 15 wherein at least a portion of the adjustment of incidence location of the beam of electrons is performed automatically by the compensation system.

17. The source system of claim 16 wherein the adjustment of the incidence location of the beam of electrons is based at least in part on one or more operating parameters.

18. The source system of claim 17 wherein the one or more operating parameters include one or more of material type, deposition rate, elapsed time, and desired deposition thickness.

19. A method for delivering a beam of electrons in an electron-beam evaporator, the method comprising:
positioning a volume of source material to be evaporated into evaporants;
generating a beam of electrons from an electron source, the generating of the beam of electrons performed to inhibit contamination of the electron source by at least some of the evaporants;
providing a trajectory for the beam of electrons to deliver the beam of electrons to an incidence location on a surface of the volume of source material; and
adjusting the incidence location upon indication that the incidence location has shifted from a desired location on the surface.

20. An electron-beam evaporator comprising:
a chamber having an interior volume, the chamber implemented to be capable of providing a desired level of vacuum for the interior volume;
a substrate holder implemented within the interior volume, the substrate holder configured to hold one or more substrates each having a surface configured to receive evaporants; and
a source system implemented within the interior volume, the source system including a holder implemented to hold a volume of source material to be evaporated into the evaporants, the source system further including an emitter assembly implemented to generate a beam of electrons, the emitter assembly including an electron source, the emitter assembly positioned relative to the holder to inhibit contamination of the electron source by at least some of the evaporants, the source system further including a beam-delivery assembly implemented to provide a trajectory for the beam of electrons from the emitter assembly to a surface of the volume of source material, the source system further including a compensation system configured to provide an adjustment of an incidence location of the beam of electrons on the surface to compensate for a shift in the incidence location from a desired location on the surface.
